(19) United States
(12) Patent Application Publication
(10) Pub. No.: US 2017/0104074 A1
(43) Pub. Date: Apr. 13, 2017

(54) III-V NITRIDE SEMICONDUCTOR DEVICE

(71) Applicant: Industrial Technology Research Institute, Hsinchu (TW)

(72) Inventors: Wei-Hung Kuo, Hsinchu City (TW); Suh-Fang Lin, Hsinchu City (TW); Kun-Fong Lin, Hsinchu City (TW); Chia-Lung Tsai, Kaohsiung City (TW)

(21) Appl. No.: 14/951,512

(22) Filed: Nov. 25, 2015

(30) Foreign Application Priority Data
Oct. 7, 2015 (TW) 104133000

(51) Int. Cl. H01L 29/20; H01L 29/34; H01L 29/45

(52) U.S. Cl. CPC H01L 29/2003; H01L 29/452; H01L 29/34

(57) ABSTRACT

In an embodiment, a III-V nitride semiconductor device comprises an AlGaN epitaxial layer and a metal electrode. The AlGaN epitaxial layer is a C-plane n-type or undoped layer, and the AlGaN epitaxial layer has an epitaxial surface consisting of one or more semi-polar planes. The metal electrode is directly formed on the one or more semi-polar planes.

### CROSS-REFERENCE TO RELATED APPLICATION

This application claims the priority benefit of Taiwan application serial no. 104133000, filed on Oct. 7, 2015. The entirety of the above-mentioned patent application is hereby incorporated by reference herein.

### TECHNICAL FIELD

The technical field relates to a III-V nitride semiconductor device.

### BACKGROUND

Nowadays, the AlGaN material system developed out of a deep ultraviolet (DUV) light-emitting diode (LED) and a photoelectric detector, has been found to be used for chemical and biological detection applications, disinfection, sterilization or military use, etc. An Al_{X}Ga_{1-X}N (X>0.4) epitaxial layer containing a high content percentage of the aluminum should be used for this series of devices of the DUV LED and the photoelectric detector. However, it would widen the energy gap and deteriorate the crystal quality as the content percentage of the aluminum in the Al_{X}Ga_{1-X}N epitaxial layer increased. Meanwhile, with respect to the GaN, the n-type AlGaN epitaxial layer has a lower doping efficiency. Therefore, it is difficult to form an Ohmic contact electrode of the n-AlGaN containing a high content percentage of the aluminum.

Currently, the research for the Ohmic contact electrode of the n-AlGaN containing a high percentage of the aluminum concentrates on different surface treatments and different metal compositions, for example, annealing under a nitrogen atmosphere before depositing a metal or combining different metals and thicknesses to manufacture electrodes.

### SUMMARY

An exemplary embodiment of the disclosure relates to a III-V nitride semiconductor device. The III-V nitride semiconductor device comprises an AlGaN epitaxial layer and a metal electrode. The AlGaN epitaxial layer is a C-plane n-type or undoped layer, and the AlGaN epitaxial layer has an epitaxial surface consisting of one or more semi-polar planes. The metal electrode is directly formed on the one or more semi-polar planes.

Another exemplary embodiment of the disclosure relates to a III-V nitride semiconductor device. The III-V nitride semiconductor device comprises an AlGaN epitaxial layer and a metal electrode. The AlGaN epitaxial layer is a C-plane n-type or undoped layer, and the AlGaN epitaxial layer has an epitaxial surface including one or more mixed planes consisting of at least one semi-polar plane and at least one polar plane. The metal electrode is directly formed on the epitaxial surface including the one or more mixed planes.

The foregoing will become better understood from a careful reading of a detailed description provided herein below with appropriate reference to the accompanying drawings.

### BRIEF DESCRIPTION OF THE DRAWINGS

FIG. 1 is a schematic diagram illustrating a cross-sectional view of a III-V nitride semiconductor device according to a first embodiment.

FIG. 2 is a schematic diagram illustrating a cross-sectional view of a III-V nitride semiconductor device according to a second embodiment.

FIG. 3 is a schematic diagram illustrating a cross-sectional view of a III-V nitride semiconductor device according to a third embodiment.

FIG. 4 is a scanning electron microscope (SEM) image illustrating a top view of the formation of a plurality of nano etching masks on a surface of an AlGaN epitaxial layer.

FIG. 5 is a SEM image illustrating a cross-sectional view of a semi-polar plane of an epitaxial surface of an AlGaN epitaxial layer.

FIG. 6 is a schematic diagram illustrating a cross-sectional view of a III-V nitride semiconductor device according to an experimental example.

FIG. 7 shows curves illustrating the current-voltage characteristics (I-V curve) of the Experimental Example, Comparative Example 1 and Comparative Example 2, respectively.

### DETAILED DESCRIPTION OF DISCLOSED EMBODIMENTS

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

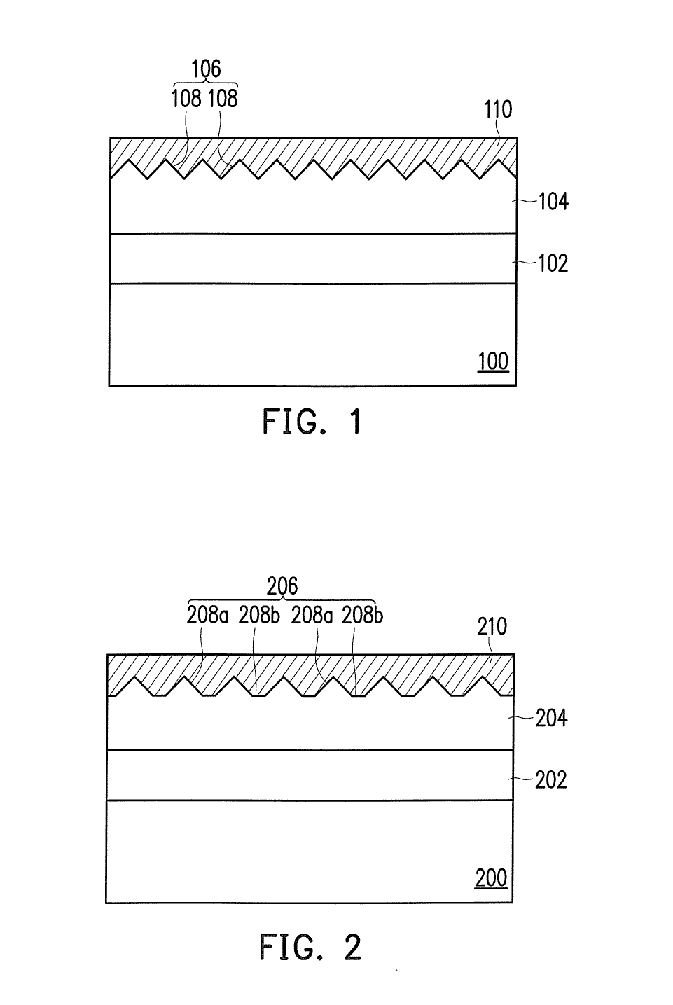

FIG. 1 is a schematic diagram illustrating a cross-sectional view of a III-V nitride semiconductor device according to a first embodiment.

Referring to FIG. 1, the III-V nitride semiconductor device of the first embodiment comprises an AlGaN epitaxial layer 104 which is formed on a substrate 100 and a buffer layer 102. The AlGaN epitaxial layer 104 is a C-plane n-type or undoped layer, i.e., the AlGaN epitaxial layer 104 may be a C-plane n-AlGaN layer or C-plane u-AlGaN layer. The AlGaN epitaxial layer 104 has an epitaxial surface 106 consisting of one or more semi-polar planes 108. A metal electrode 110 is directly formed on the semi-polar planes 108, wherein the metal electrode 110 such as titanium-aluminum (Ti—Al) based or vanadium (V) based. The substrate 100 may be a sapphire substrate or a substrate of other materials such as a c-plane sapphire substrate or a Si substrate for the semiconductor device. The buffer layer 102 may be, but not limited to an aluminum nitride (AlN) layer.

In the first embodiment, the content percentage of the aluminium in the AlGaN epitaxial layer 104 may be, but not limited to an atomic percentage ranged from 5% to 90%. The III-V nitride semiconductor device may be, but not limited to a Deep ultraviolet light emitting diode (UV LED), an UV light detector diode, a GaN high electron mobility transistor (GaN HEMI). Thus, in an exemplar, the atomic percentage of the aluminum in the AlGaN epitaxial layer 104 may be ranged from 60% to 90%, but the present disclosure is not limited thereto. In other words, according to the embodiment, the III-V nitride semiconductor device has an n-AlGaN or u-AlGaN epitaxial layer.

In the embodiment, the semi-polar planes 108 are used as a contact surface of the III-V nitride semiconductor device interfacing with the metal electrode 110. This reduces the potential energy barrier of the metal electrode and the contact surface of the III-V nitride semiconductor device, therefore, an Ohmic contact electrode may be formed by a tunneling technology.

FIG. 2 is a schematic diagram illustrating a cross-sectional view of a III-V nitride semiconductor device according to a second embodiment. Referring to FIG. 2, the III-V nitride semiconductor device according to the present embodiment comprises an AlGaN epitaxial layer 204 formed on a substrate 200 and a buffer layer 202. The AlGaN epitaxial layer 204 is a C-plane n-type or undoped layer. The AlGaN epitaxial layer 204 has an epitaxial surface 206 consisting of at least one semi-polar plane 208a and at least one polar plane 208b. A metal electrode 210 is directly formed on the epitaxial surface 206 including one or more mixed planes consisting of at least one semi-polar plane 208a and at least one polar plane 208b.

In the second embodiment, the exemplars regarding to the content percentage of the aluminium in the AlGaN epitaxial layer 204, the material of the metal electrode 210, the substrate 200 and the buffer layer 202 may refer to those in the first embodiment. In the second embodiment, the III-V nitride semiconductor device may be a Deep ultraviolet light emitting diode (UV LED), an UV light detector diode, a GaN high electron mobility transistor (GaN HEMT), or a device having at least one n-AlGaN electrode or u-AlGaN electrode.

As aforementioned, the metal electrode 210 is directly contacted with the epitaxial surface 206 including one or more mixed planes consisting of at least one semi-polar plane 208a and at least one polar plane 208b. This reduces the contact resistance of the AlGaN epitaxial layer 204. Also, the content percentage of the aluminium in the n-AlGaN epitaxial layer is significantly reduced; therefore, an Ohmic contact electrode may be formed.

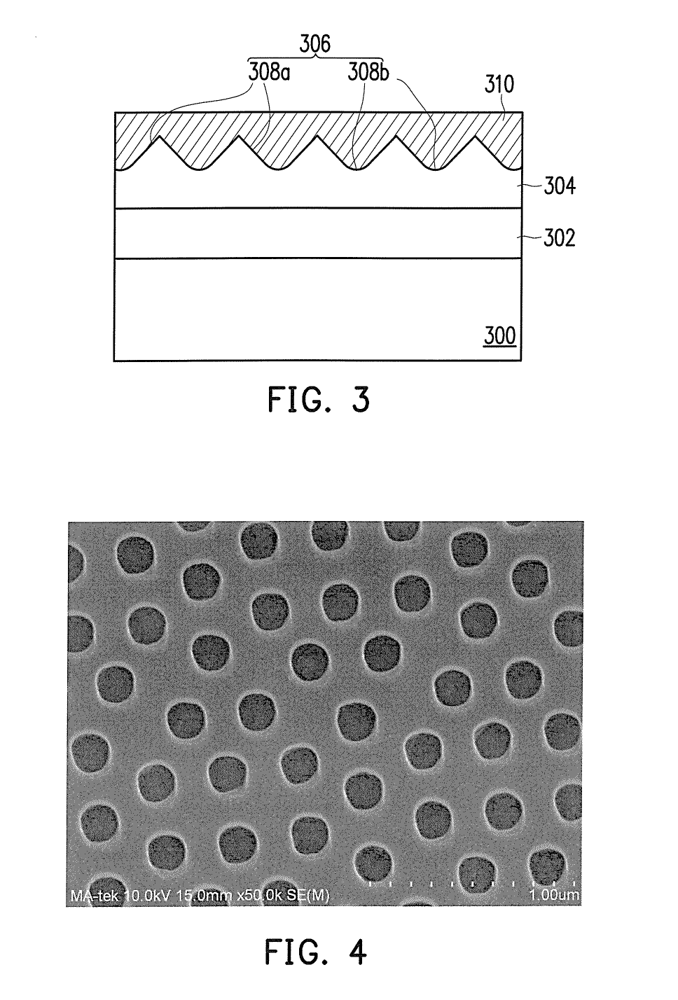

FIG. 3 is a schematic diagram illustrating a cross-sectional view of a III-V nitride semiconductor device according to a third embodiment. Referring to FIG. 3, the III-V nitride semiconductor device comprises an AlGaN epitaxial layer 304 and a metal electrode 310, and the AlGaN epitaxial layer 304 and the metal electrode 310 are formed on a substrate 300 and a buffer layer 302. Wherein an epitaxial surface 306 of the AlGaN epitaxial layer 304 is similar to that in the second embodiment. The epitaxial surface 306 consisting of at least one semi-polar plane 308a and at least one polar plane 308b. Unlike in the second embodiment, the polar planes 308b in the third embodiment is arc shaped and upwardly concave, but not flat. Other exemplars for the III-V nitride semiconductor device in the third embodiment may refer to those described in the first or second embodiment.

Examples are cited to validate the efficacy of the present disclosure, but the scope of the present disclosure being indicated may be, but not limited to these experimental examples set forth herein.

### Experimental Example

First, An AlN buffer layer of 2000 nm thick is grown on a 2-inch C-plane sapphire substrate by a metal organic chemical-vapor deposition (MOCVD). Then a silicon doped n-type Al_{0.63}GaN epitaxial layer having a thickness of 2000 nm is grown, and a carrier concentration is 5E18/cm³ obtained by the Hall measurement.

Thereafter, a plurality of nano etching masks is formed on a surface of the n-type Al_{0.63}GaN epitaxial layer by a Nano Imprint (NIP) technology. FIG. 4 shows a top view of a scanning electron microscope (SEM) image. In FIG. 4, the nano etching masks are dark and slightly circular, wherein a distribution size of nano-rods has a pitch of 450 nm, a fill factor is 1, and a thickness of the nano etching masks is 100 nm.

Next, the nano etching masks are used to perform a dry etching process by an Inductively Coupled Plasma (ICP) equipment. The criterions for performing the dry etching are as follows. The etching gas is Cl₂: 8 sccm/BCl₃: 2 sccm, the Coil power is 175 W, the plate power is 100 W, the pressure is 10 mtorr, and a depth of the dry etching is around 150 nm. The nano etching masks are removed after the dry etching is completed.

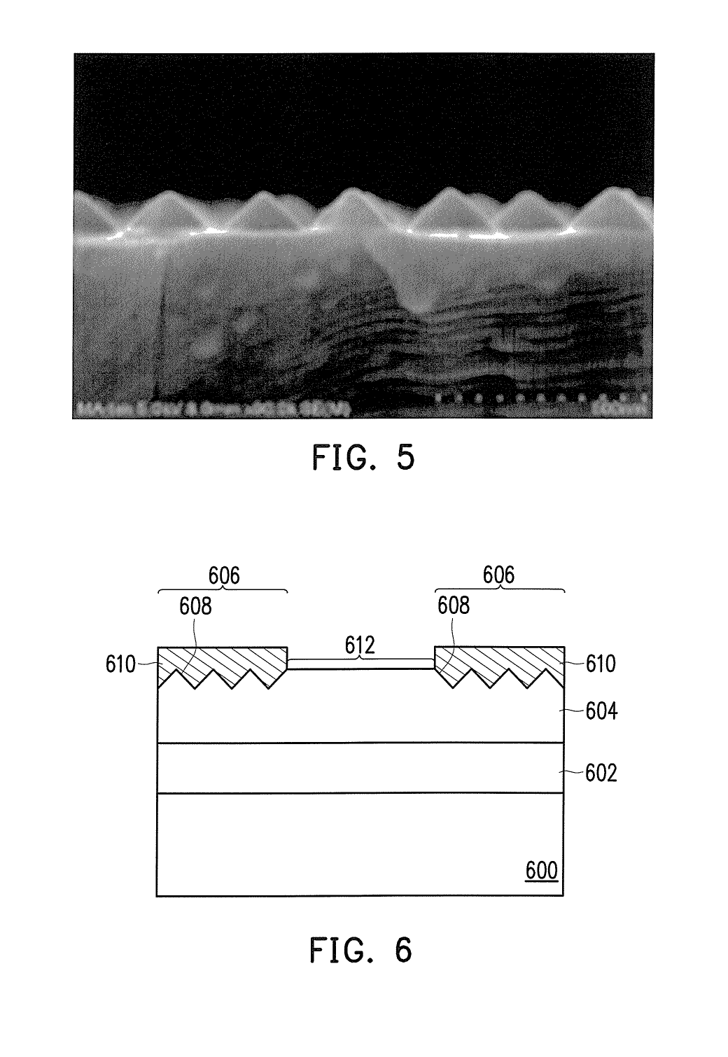

An Al_{0.63}GaN epitaxial layer is formed after completing the dry etching, as shown in FIG. 5, wherein FIG. 5 is a SEM image illustrating a cross-sectional view of the Al_{0.63}GaN epitaxial layer. The Al_{0.63}GaN epitaxial layer has at least one semi-polar plane with regularity, while the polar plane has been eliminated. Then, a rapid thermal annealing (RTA) treatment of surface recovery is performed at 800° C. under a nitrogen atmosphere for one minute.

Then, a Ti—Al based metal electrode of titanium (150 nm)-aluminum (400 nm) is directly formed on the Al_{0.63}GaN epitaxial layer having the at least one semi-polar plane. And, a RTA treatment is performed at 600° C. under a nitrogen atmosphere for one minute, so that an Ohmic contact electrode is formed.

FIG. 6 is a schematic diagram illustrating a cross-sectional view of a III-V nitride semiconductor device according to an experimental example, which shows a 2-inch C-plane sapphire substrate 600, an AlN buffer layer 602, a silicon doped n-type A10.63GaN epitaxial layer 604, an epitaxial surface 606, a semi-polar planes 608, and a metal electrode 610. An area indicated by a reference number 612 does not contact with the metal electrode 610, which does not require the formation of an Ohmic contact electrode. Therefore, the epitaxial surface 606 may be a polarized epitaxial surface.

### Comparative Example 1

According to an experimental example, a III-V nitride semiconductor device is manufactured. After a silicon doped n-type Al0.63GaN epitaxial layer having a thickness of 2000 nm is grown, a Ti—Al based metal electrode of titanium (150 nm)-aluminum (400 nm) is directly formed without further processing on the epitaxial layer.

### Comparative Example 2

According to an experimental example, a III-V nitride semiconductor device is manufactured. After a silicon doped n-type Al_{0.63}GaN epitaxial layer having a thickness of 2000 nm is grown, a Dot pattern of a micron level is formed as an etching mask by using a photolithography process. Wherein a distribution size of the Dot pattern has a pitch of 9 μm, a fill factor is 4/5, and a thickness of the Dot pattern is 15 μm. Then, the Dot pattern is used as an etching mask to perform a dry etching process by an ICP equipment. The criterions for performing the dry etching are as follows. The etching gas is Cl₂:8 sccm/BCl₃:2 sccm, the Coil power is 175 W, the plate power is 100 W, the pressure is 3 mtorr, and a depth of the dry etching is around 150 nm. An epitaxial surface including at least one mixed plane consisting of at least one semi-polar plane and at least one polar plane is formed after the dry etching is completed. The subsequent manufacturing process is the same as that of the experimental example, and is not repeated herein.

### Detection

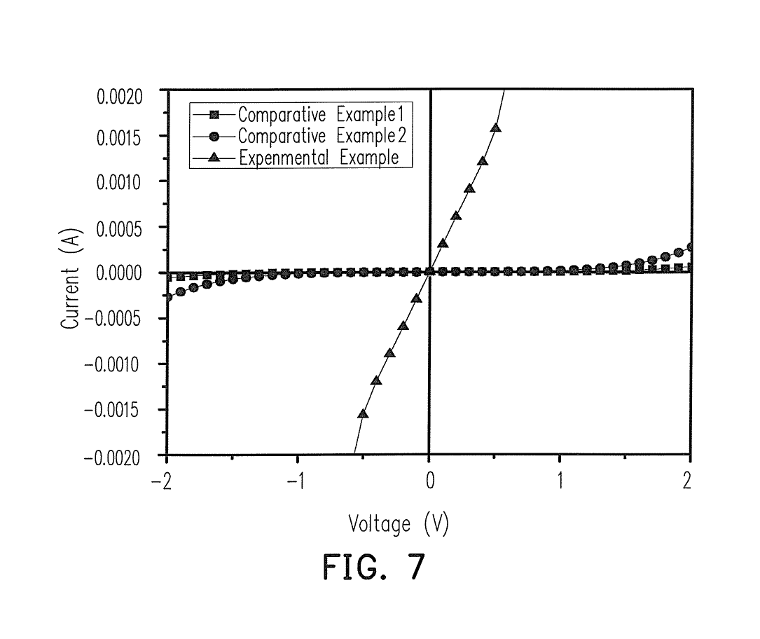

An electricity measurement of a III-V nitride semiconductor device is performed respectively according to an Experimental Example, Comparative Example 1 and Comparative Example 2, as shown in FIG. 7. It may be seen from FIG. 7, the Ohmic contact is not formed in both the Comparative Examples 1 and 2. This may cause the contact resistance to be too high. While, the epitaxial surface 606 consisting of the at least one semi-polar plane 608 in the Experimental example appears an Ohmic contact, and its contact resistivity Rc is 1.5E-3 (ohm-cm²). Therefore, the exemplary embodiments of the present disclosure do help to manufacture an Ohmic contact electrode.

From the aforementioned exemplary embodiments of the disclosure, an content percentage of the aluminum in the AlGaN epitaxial layer may be ranged from 5% to 90%; an atomic percentage of the aluminum in the AlGaN epitaxial layer may be ranged from 60% to 90%; the epitaxial surface may be formed by a Nano Imprint (NIP) technology and a dry etching process; the metal electrode may be Ti—Al based or V-based; and the III-V nitride semiconductor device may further comprise an UV light emitting diode, an UV light detector diode, a GaN high electron mobility transistor (GaN HEMT) or a device having an n-AlGaN or u-AlGaN electrode.

Accordingly, by directly forming the metal electrode on a N-type aluminum gallium nitride (N—AlGaN) having at least one complete or partial semi-polar plane, the exemplary embodiments of present disclosure reduce the potential energy barrier of the metal electrode and the contact surface of the semiconductor device, therefore, an Ohmic contact electrode is formed. This resolves the issue of Joule heating caused by the high resistance of the contact electrode; therefore, the efficiency of the semiconductor device is enhanced.

In summary, the present disclosure uses the epitaxial surface of the aluminum gallium nitride (AlGaN) consisting of complete or partial semi-polar planes as a contact surface contacting with the metals, and thus it may reduce the potential energy barrier of the epitaxial surface of the c-plane AlGaN and the contact surface contacting with the metals. So that, an Ohmic contact electrode is formed by a way of tunneling. And, the potential energy barrier is significantly reduced between the n-AlGaN epitaxial layer containing a high percentage of the aluminum and the metal electrode. Therefore, the semiconductor device of the present disclosure is applicable to such as a deep ultraviolet LED, an UV light detector diode, a GaN high electron mobility transistor (GaN HEMT) and an Ohmic electrode having the epitaxial layer containing a high percentage of the aluminum. Also, it solves the manufacturing problems of the electrodes of a device having a material of a wide energy gap, and resolves the issues of the high resistance and the device overheating, therefore, the device characteristics are improved.

It will be apparent to those skilled in the art that various modifications and variations can be made to the disclosed embodiments. It is intended that the specification and examples be considered as exemplary embodiments only, with a scope of the disclosure being indicated by the following claims and their equivalents.

1. A III-V nitride semiconductor device, comprising:
an AlGaN epitaxial layer having an epitaxial surface consisting of one or more semi-polar planes, wherein the AlGaN epitaxial layer is a n type or undoped layer having a C-plane as an epitaxial growth plane, wherein the one or more semi-polar planes are arranged in a form of a periodic structure; and
a metal electrode, directly formed on the one or more semi-polar planes.

2. The III-V nitride semiconductor device of claim 1, wherein an atomic percentage of aluminum in the AlGaN epitaxial layer is ranged from 5% to 90%.

3. The III-V nitride semiconductor device of claim 2, wherein the atomic percentage of aluminum of the AlGaN epitaxial layer is ranged from 60% to 90%.

4. The III-V nitride semiconductor device of claim 1, wherein the epitaxial surface is formed by a Nano Imprint technology and a dry etching process.

5. The III-V nitride semiconductor device of claim 1, wherein the metal electrode is titanium-aluminum based or vanadium based.

6. The III-V nitride semiconductor device of claim 1, wherein the III-V nitride semiconductor device further includes an ultraviolet (UV) light emitting diode, an UV light detector diode, a GaN high electron mobility transistor, or a device having a n-AlGaN electrode or an u-AlGaN electrode.

7. A III-V nitride semiconductor device, comprising:
an AlGaN epitaxial layer including an epitaxial surface having one or more mixed planes consisting of at least one semi-polar plane and at least one polar plane, wherein the AlGaN epitaxial layer is a n type or undoped layer having a C-plane as an epitaxial growth plane, wherein the one or more semi-polar planes are arranged in a form of a periodic structure; and
a metal electrode, directly formed on the epitaxial surface having the one or more mixed planes consisting of the at least one semi-polar plane and the at least one polar plane.

8. The III-V nitride semiconductor device of claim 7, wherein an atomic percentage of aluminum in the AlGaN epitaxial layer is ranged from 5% to 90%.

9. The III-V nitride semiconductor device of claim 8, wherein the atomic percentage of aluminum in the AlGaN epitaxial layer is ranged from 60% to 90%.

10. The III-V nitride semiconductor device of claim 7, wherein the epitaxial surface is formed by a Nano Imprint technology and a dry etching process.

11. The III-V nitride semiconductor device of claim 7, wherein the metal electrode is titanium-aluminum based or vanadium based.

12. The III-V nitride semiconductor device of claim 7, wherein the III-V nitride semiconductor device further includes an ultraviolet (UV) light emitting diode, an UV light detector diode, a GaN high electron mobility transistor, or a device having a n-AlGaN electrode or an u-AlGaN electrode.
